(19) United States
(12) Patent Application Publication
(10) Pub. No.: US 2024/0356521 A1
(43) Pub. Date: Oct. 24, 2024

(54) ACOUSTIC WAVE DEVICE AND METHOD FOR PRODUCING SAME

(71) Applicant: Sanan Japan Technology Corporation, Tokyo (JP)

(72) Inventors: SUBEI SHUN, Tokyo (JP); Hiroshi Nakamura, Tokyo (JP); Shinichi Shioi, Tokyo (JP)

(73) Assignee: Sanan Japan Technology Corporation, Tokyo (JP)

(21) Appl. No.: 18/642,257

(22) Filed: Apr. 22, 2024

(30) Foreign Application Priority Data
Apr. 22, 2023 (JP) 2023-070518

(51) Int. Cl. H03H 9/02; H03H 3/08; H03H 9/64

(52) U.S. Cl. CPC H03H 9/02866; H03H 3/08; H03H 9/02551; H03H 9/02574; H03H 9/6483

(57) ABSTRACT

An acoustic wave device includes a support substrate, a medium layer formed on the support substrate, a piezoelectric substrate formed on the medium layer, and a resonator formed on the piezoelectric substrate. The medium layer includes a first acoustic velocity region and second acoustic velocity regions penetrating at least one half of the thickness of the medium layer. The second acoustic velocity region has an acoustic velocity different from that of the first acoustic velocity region.

### CROSS-REFERENCE TO RELATED APPLICATION(S)

This application claims priority to Japanese Application No. 2023-070518, filed Apr. 22, 2023, which are incorporated herein by reference, in their entirety, for any purpose.

### BACKGROUND OF THE INVENTION

### Field of the Invention

The present disclosure relates to an acoustic wave device and a method for producing the same. More specifically, the present disclosure relates to a surface acoustic wave device using SH wave, such as a filter, a duplexer, or a multiplexer.

### Background Art

High-frequency communication system for mobile communication terminals typified by smartphones adopts a high-frequency filter or the like to remove unnecessary signals other than signals in the frequency band used for communication.

The acoustic wave device having a surface acoustic wave (SAW: Surface Acoustic Wave) element is used as a high-frequency filter or the like. The SAW element is the element that includes IDT (Interdigital Transducer) having a pair of comb-shaped electrodes on a piezoelectric substrate.

Surface acoustic wave devices are produced as follows. A piezoelectric substrate propagating an acoustic wave and a multilayer film substrate bonding a support substrate having thermal expansion coefficient lower than that of the piezoelectric substrate are formed. Next, a plurality of IDT electrodes are formed on the multilayer film substrate using a photolithography technique, and then a surface acoustic wave device is cut into a predetermined size by dicing. The support substrate suppresses the change in the size of the piezoelectric substrate when the temperature changes by using the multilayer film substrate, as a result, this producing method can stabilize frequency characteristic of the acoustic wave device.

According to Patent Document 1 (JP2009-278610) and the like, in order to improve the temperature characteristics of an acoustic wave device, it is known that a support substrate such as a sapphire substrate having a high Young's modulus and a low linear expansion coefficient is bonded to a piezoelectric substrate to suppress expansion and contraction due to temperature change.

As disclosed in Patent Document 1, in order to improve the temperature characteristics of an acoustic wave device, it is known that a support substrate such as a sapphire substrate having a high Young's modulus and a low linear expansion coefficient is bonded to a piezoelectric substrate to suppress expansion and contraction due to temperature change. However, spurious wave sometimes occurs particularly on the high-frequency side in such support substrate, and the filter characteristics are inferior.

### SUMMARY OF THE INVENTION

Some examples described herein may address the above-described problems. Some examples described herein may have an object to provide an acoustic wave device having a superior temperature characteristic and a more suppressed spurious property, and a method for producing the same.

In some examples, an acoustic wave device includes a support substrate, a medium layer formed on the support substrate, a piezoelectric substrate formed on the medium layer, and a resonator formed on the piezoelectric substrate. The medium layer includes an acoustic wave device having a first acoustic velocity region and a second acoustic velocity region penetrating at least one half of the thickness of the medium layer. The second acoustic velocity region has an acoustic velocity different from that of the first acoustic velocity region.

### BRIEF DESCRIPTION OF THE DRAWING

FIG. 1 is a cross-sectional view of an acoustic wave device 1 according to a first embodiment.

FIG. 2 is a cross-sectional showing a device chip 5 of the acoustic wave device 1 according to the first embodiment.

FIG. 3 is a perspective view seeing through the device chip 5 of the acoustic wave device 1.

FIG. 4 is a diagram showing an example of patterns of second acoustic velocity regions 12B.

FIG. 5 is a diagram showing an example of acoustic wave elements 50 of the acoustic wave device 1 according to the first embodiment.

FIG. 6 is a cross-sectional showing a device chip 5 of the acoustic wave device 1 according to a second embodiment.

FIG. 7 is a cross-sectional showing a device chip 5 of the acoustic wave device 1 according to a third embodiment.

FIG. 8 is a diagram for explaining a method for producing the acoustic wave device 1.

FIG. 9 is a diagram for explaining a method for producing the acoustic wave device 1 according to the second embodiment.

FIG. 10 is a diagram for explaining a second method for producing the acoustic wave device 1.

FIG. 11 is a diagram for explaining a method for producing the acoustic wave device 1 according to the third embodiment.

FIG. 12 is a longitudinal sectional view of a module to which the acoustic wave device 1 is applied according from the first embodiment to the third embodiment.

### DETAILED DESCRIPTION

The embodiments will be described with reference to the accompanying drawings. In the drawings, the same or corresponding parts are denoted by the same reference numerals. Duplicate descriptions of such portions may be simplified or omitted.

### First Embodiment

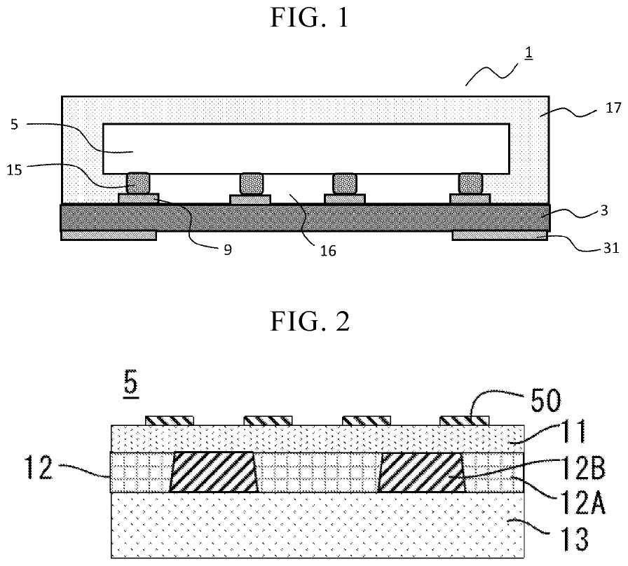

FIG. 1 is a cross-sectional view of an acoustic wave device 1 according to a first embodiment.

As shown in FIG. 1, the acoustic wave device 1 includes a wiring substrate 3, external connection terminals 31, a device chip 5, electrode pads 9, bumps 15, and a sealing portion 17.

The wiring substrate 3 is a multilayer substrate made of resin. For example, the wiring substrate 3 is a low-temperature co-fired ceramic (Low Temperature Co-Fired Ceramics: LTCC) multilayer substrate includes a plurality of dielectric layers.

The plurality of external connection terminals 31 are formed on the lower surface of the wiring substrate 3.

The plurality of electrode pads 9 are formed on the main surface of the wiring substrate 3. For example, the electrode pads 9 are formed of copper or an alloy containing copper. For example, the electrode pads 9 have the thickness of 10 μm to 20 μm.

The bumps 15 are formed on each upper surface of the electrode pads 9. The bumps 15 are gold bumps for example. The bump 15 has the height of 10 μm to 50 μm for example.

An air gap 16 is formed between the wiring substrate 3 and the device chip 5.

The device chip 5 is mounted on the wiring substrate 3 via the bumps 15 by flip-chip bonding. The device chip 5 is electrically connected to the plurality of electrode pads 9 via the plurality of bumps 15.

The device chip 5 is a substrate on which acoustic wave elements 50 are formed. For example, a transmitting filter and a reception filter including the plurality of acoustic wave elements 50 are formed on the main surface of the device chip 5.

The transmitting filter is formed so that an electrical signal of a desired frequency band can pass through. For example, the transmitting filter is a ladder filter including a plurality of series resonators and a plurality of parallel resonators.

The reception filter is formed so that an electrical signal of a desired frequency band can pass through. For example, the reception filter is a ladder filter.

The sealing portion 17 is formed so as to cover the device chip 5. For example, the sealing portion 17 is formed of an insulator such as a synthetic resin. In some examples, the sealing portion 17 is made of metal.

In case the sealing portion 17 is made of a synthetic resin, epoxy resin, polyimide, or the like can be used as the synthetic resin. Preferably, an epoxy resin is used to form the sealing portion 17 with a low temperature curing process.

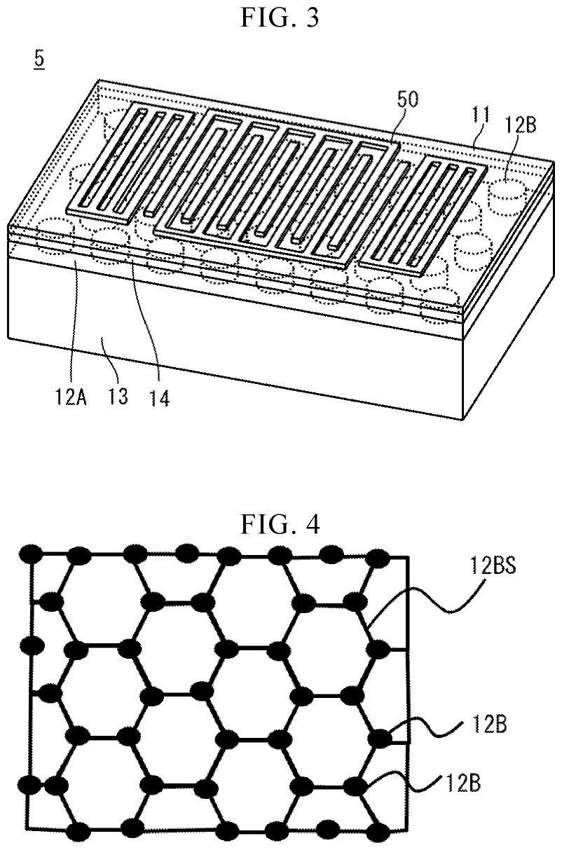

FIG. 2 is a cross-sectional showing the device chip 5 of the acoustic wave device 1 according to the first embodiment.

As shown in FIG. 2, the device chip 5 includes a piezoelectric substrate 11, a medium layer 12, and a support substrate 13. The acoustic wave elements 50 are formed on the piezoelectric substrate 11.

The piezoelectric substrate 11 is, for example, a substrate made of a piezoelectric single crystal such as lithium tantalate, lithium niobate, or quartz. In other example, the piezoelectric substrate 11 is a substrate made of piezoelectric ceramics.

The thickness of the piezoelectric substrate 11 may be 0.3 μm to 5 μm for example.

The medium layer 12 includes first acoustic velocity regions 12A and second acoustic velocity regions 12B. The first acoustic velocity regions 12A are made of, for example, silicon nitride, silicon oxynitride, silicon, alumina, silicon dioxide, or silicon carbide. The second acoustic velocity regions 12B are made of, for example, silicon nitride, silicon oxynitride, silicon, alumina, silicon dioxide, silicon carbide, germanium, tungsten, platinum, or iridium, but is made of a material except the material employed in the first acoustic velocity regions 12A.

As shown in FIG. 2, the second acoustic velocity regions 12B may be formed through the first acoustic velocity regions 12A. That is, the medium layer 12 may be formed so that the second acoustic velocity regions 12B is exposed on the piezoelectric substrate 11 side and on the support substrate 13 side. The second acoustic velocity regions 12B may be formed to have the thickness of one-half or more of the thickness of the medium layer 12.

According to another example, the medium layer 12 may be formed such that the second acoustic velocity regions 12B are not exposed to the piezoelectric substrate 11 side.

Further, according to another example, the medium layer 12 may be formed so that the second acoustic velocity regions 12B are not exposed to the support substrate 13 side.

The first acoustic velocity regions 12A and the second acoustic velocity regions 12B are configured such that the average acoustic velocity of the bulk wave propagating through the medium layer 12 is higher than the velocity of the acoustic wave in the main mode excited by the acoustic wave elements 50 as a resonator. The velocity of the acoustic wave in the main mode excited by the acoustic wave element 50 as a resonator is the acoustic velocity determined by the resonance frequency and the structure of the resonator. The average acoustic velocity is represented by (L1+L2)/((L1/V1)+(L2/V2)) when an acoustic wave passes through a medium consisting of a first medium (length is L1 and acoustic velocity is V1) and a second medium (length is L2 and acoustic velocity is V2).

According to an example, the average acoustic velocity of the bulk wave propagating through the medium layer 12 may be from 4500 m/s to 5500 m/s.

This facilitates confinement of the acoustic wave in the piezoelectric substrate 11. The average acoustic velocity of the bulk wave propagating through the medium layer 12 is preferably 1.1 times or more, more preferably 1.2 times or more, and even more preferably 1.3 times or more than the acoustic velocity of the bulk wave propagating through the piezoelectric substrate 11. If the average acoustic velocity of the bulk waves propagating through the medium layer 12 is too high, the bulk waves tend to be reflected at the boundary between the medium layer 12 and the piezoelectric substrate 11, which may increase spurious.

Therefore, the average acoustic velocity of the bulk wave propagating through the medium layer 12 is preferably 2.5 times or less, more preferably 2.0 times or less than the acoustic velocity of the bulk wave propagating through the piezoelectric substrate 11. Even if the acoustic velocity of the bulk wave propagating in the second acoustic velocity regions 12B is 2.5 times or more than the acoustic velocity of the bulk wave propagating in the piezoelectric substrate 11, it is desirable to arrange the second acoustic velocity regions 12B so that the bulk wave reflected in the second acoustic velocity regions 12B does not resonate.

It is desirable that the acoustic velocity of the bulk wave propagating through the support substrate 13 is 2.0 times or less than the average acoustic velocity of the bulk wave propagating through the medium layer 12. This is because if the acoustic velocity of the bulk wave propagating through the support substrate 13 is excessively higher than the average acoustic velocity of the bulk wave propagating through the medium layer 12, the bulk wave is likely to be reflected by the support substrate 13 and spurious may be increased. Even if the acoustic velocity of the bulk wave propagating through the second acoustic velocity regions 12B is 2.5 times or more than the acoustic velocity of the bulk wave propagating through the piezoelectric substrate 11 in the medium layer 12, the second acoustic velocity regions 12B can be arranged so that the bulk wave reflected in the second acoustic velocity regions 12B do not resonate. As the result, the average acoustic velocity of the bulk waves propagating through the medium layer 12 can be increased, and the difference in the acoustic velocity of the bulk waves propagating through the support substrate 13 can be reduced.

The support substrate 13 may be made of, for example, sapphire, silicon, alumina, spinel, silicon nitride, aluminum nitride, silicon carbide, silicon oxynitride, diamond, quartz, glass, or the like. The smaller thermal expansion coefficient of the support substrate 13 is the better. This is because the temperature characteristic of the acoustic wave device 1 is improved. A sapphire substrate having a small thermal expansion coefficient includes a high Young's modulus, and makes it difficult to employ surface processing techniques forming an uneven shape or a jagged shape and yield rate low. Therefore, it is desirable that the support substrate 13 has a flat rectangular parallelepiped shape.

The thickness of the support substrate 13 may be, for example, 50 μm to 200 μm.

FIG. 3 is a perspective view seeing through the device chip 5 of the acoustic wave device 1. As shown in FIG. 3, the second acoustic velocity regions 12B include a plurality of divided regions. In addition, three or more second acoustic velocity regions 12B are formed in a region where one resonator (the acoustic wave element 50) is formed. As shown in FIG. 3, ten or more, or twenty or more the second acoustic velocity regions 12B may be formed in the region where one resonator (the acoustic wave element 50) is formed. The more second acoustic velocity regions 12B are formed, the more the reflection of the bulk waves propagating through the piezoelectric substrate 11 are scattered and the spurious is more suppressed.

As shown in FIG. 3, the top view shape of the second acoustic velocity regions 12B may be a circular shape. According to another example, it may be oval, polygonal, or any combinations of these shapes. The size may be changed appropriately.

The average area in the top view of all second acoustic velocity regions 12B can be, for example, 0.1 μm² to 500 μm². The number, area, shape and arrangement of the second acoustic velocity regions 12B in the top view are appropriately designed depending on how to control the bulk waves propagating through the piezoelectric substrate 11.

As shown in FIG. 3, the solid shape of the second acoustic velocity regions 12B may be cylindrical shape. According to another example, the shape may be a truncated conic shape, a truncated triangular pyramidal shape, a triangular prismatic shape, a truncated quadrangular pyramidal shape, or a quadrangular prismatic shape. It may be a more polygonal truncated pyramidal shape, a prismatic shape, or any combinations of these solid shapes. The size may be changed appropriately. The number, area, shape and arrangement of the second acoustic velocity regions 12B in the top view is appropriately designed depending on how to control the bulk waves propagating through the piezoelectric substrate 11.

FIG. 3 shows the example that the second acoustic velocity regions 12B are formed to be divided into a plurality of regions, but it is not limited. FIG. 4 is a diagram showing an example of patterns of the second acoustic velocity regions 12B. As shown in FIG. 4, the plurality of the second acoustic velocity regions 12B interspersed may be connected to each other in series, for example, by a second acoustic velocity region 12BS including a thinner straight line or a curved stripe shape. As shown in FIG. 4, the plurality of the second acoustic velocity regions 12B interspersed may be connected to each other in series, for example, by a stripe shaped second acoustic velocity region 12BS including a thinner straight line or a curved stripe shape even though these are connected to each other in series by the stripe shaped second acoustic velocity region 12BS.

As shown in FIG. 3, the device chip 5 may include a second medium layer 14 formed between the medium layer 12 and the piezoelectric substrate 11. The second medium layer 14 will be described later in the embodiment 2.

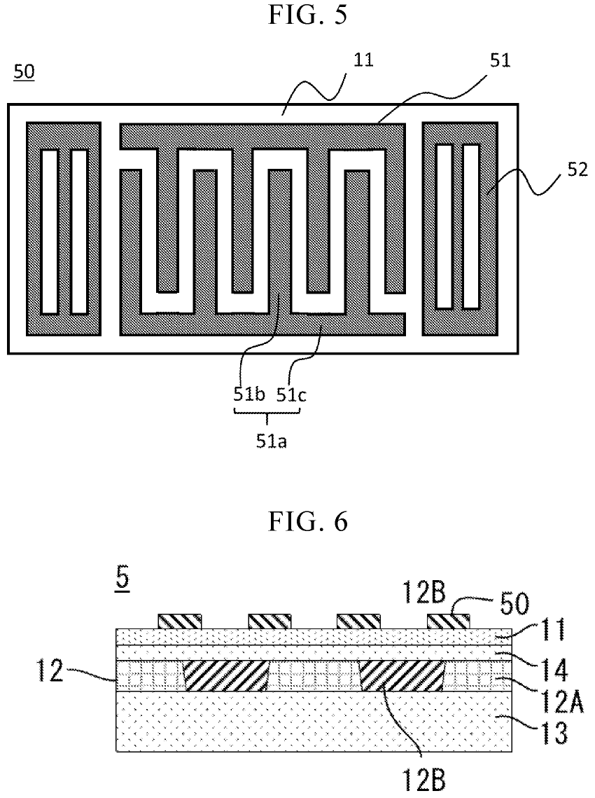

Next, an example of the acoustic wave elements 50 formed on the piezoelectric substrate 11 will be described with reference to FIG. 5. FIG. 5 is a diagram showing the example of acoustic wave elements 50 of the acoustic wave device 1 according to the first embodiment.

As shown in FIG. 5, IDT (Interdigital Transducer) electrodes 51 and a pair of reflectors 52 are formed on the main surface of the piezoelectric substrate 11. The IDT electrodes 51 and the pair of reflectors 52 are provided so as to excite acoustic waves (mainly SH waves).

The IDT electrodes 51 and the pair of reflectors 52 are made of an alloy of aluminum and copper for example. The IDT electrodes 51 and the pair of reflectors 52 are made of a suitable metal such as aluminum, molybdenum, iridium, tungsten, cobalt, nickel, ruthenium, chromium, strontium, titanium, palladium, or silver, or an alloy thereof.

The IDT electrodes 51 and the pair of reflectors 52 are formed of a laminated metal film in which a plurality of metal layers are laminated. The thicknesses of the IDT electrodes 51 and the pair of reflectors 52 have the thickness of 150 nm to 450 nm for example.

The IDT electrodes 51 include a pair of comb-shaped electrodes 51a. The pair of comb-shaped electrodes 51a are opposed to each other. The comb-shaped electrodes 51a include a plurality of electrode fingers 51b and a busbar 51c.

The plurality of fingers 51b are longitudinally aligned. The busbar 51c connects the plurality of fingers 51b.

One of the pair of reflectors 52 adjoins one side of the IDT electrodes 51. The other of the pair of reflectors 52 adjoins the other side of IDT electrodes 51.

According to the first embodiment described above, it is possible to provide an acoustic wave device having superior temperature characteristics and more suppressing spurious.

### Second Embodiment

FIG. 6 is a cross-sectional showing the device chip 5 of the acoustic wave device 1 according to a second embodiment. As shown in FIG. 6, the device chip 5 according to the second embodiment includes the second medium layer 14 disposed between the piezoelectric substrate 11 and the medium layer 12.

The second medium layer 14 can be appropriately formed of a material such as silicon nitride, silicon oxynitride, silicon, alumina, silicon dioxide, silicon carbide, or the like. The thickness of the second medium layer 14 may be, for example, 0.1 μm to 5 μm.

The second medium layer 14 primarily controls the bulk waves propagating through the piezoelectric substrate 11 by a predetermined acoustic velocity and propagates the bulk waves to the medium layer 12. This increases the number of options for the design to more suppress spurious or improve the Q value. According to another example, the second medium layer 14 may be employed, for example, in a case where a metallic material is used as the material of the second acoustic velocity regions 12B exposed to the piezoelectric substrate 11, for example, in a case where the piezoelectric substrate 11 is thinned to 1μ or less, or in a case where a parasitic capacitance such as an effect on the high frequency properties of the acoustic wave device 1 is generated. According to another example, the second medium layer 14 may be employed in a case where the medium layer 12 is formed using a material that hinders the bonding between the medium layer 12 and the piezoelectric substrate 11.

The first acoustic velocity regions 12A and the second acoustic velocity regions 12B are configured so that the average acoustic velocity of the bulk wave propagating through the medium layer 12 is higher than the velocity of the acoustic wave of the main mode excited by the acoustic wave elements 50 as a resonator. The velocity of the acoustic wave in the main mode excited by the acoustic wave elements 50 as a resonator is the acoustic velocity determined by the resonance frequency and the structure of the resonator. The average acoustic velocity is represented by (L1+L2)/((L1/V1)+(L2/V2)) when an acoustic wave passes through a medium consisting of a first medium (length is L1 and acoustic velocity is V1) and a second medium (length is L2 and acoustic velocity is V2).

According to an example, the average acoustic velocity of the bulk wave propagating through the medium 12 may be from 4500 m/s to 5500 m/s. This facilitates confinement of the acoustic wave in the piezoelectric substrate 11 and the second medium layer 14. The average acoustic velocity of the bulk wave propagating through the medium layer 12 is preferably 1.1 times or more, more preferably 1.2 times or more, and even more preferably 1.3 times or more than the acoustic velocity of the bulk wave propagating through the piezoelectric substrate 11. If the average acoustic velocity of the bulk waves propagating through the medium layer 12 is too high, the bulk waves tend to be reflected at the boundary between the medium layer 12 and the piezoelectric substrate 11, which may increase spurious.

Therefore, the average acoustic velocity of the bulk wave propagating through the medium layer 12 is preferably 2.5 times or less, more preferably 2.0 times or less than the acoustic velocity of the bulk wave propagating through the piezoelectric substrate 11. Even if the acoustic velocity of the bulk wave propagating in the second acoustic velocity region 12B is 2.5 times or more than the acoustic velocity of the bulk wave propagating in the piezoelectric substrate 11, it is desirable to arrange the second acoustic velocity region 12B so that the bulk wave reflected in the second acoustic velocity region 12B does not resonate.

It is desirable that the acoustic velocity of the bulk wave propagating through the support substrate 13 is 2.0 times or less than the average acoustic velocity of the bulk wave propagating through the medium layer 12. This is because if the acoustic velocity of the bulk wave propagating through the support substrate 13 is excessively higher than the average acoustic velocity of the bulk wave propagating through the medium layer 12, the bulk wave is likely to be reflected by the support substrate 13 and spurious may be increased. Even if the acoustic velocity of the bulk wave propagating through 2B is 2.5 times or more than the acoustic velocity of the bulk wave propagating through the second medium layer 14 in the medium layer 12, the second acoustic velocity region 12B can be arranged so that the bulk wave reflected in the second acoustic velocity region 12B does not resonate. As the result, the average acoustic velocity of the bulk waves propagating through the medium layer 12 can be increased, and the difference in the acoustic velocity of the bulk waves propagating through the support substrate 13 can be reduced.

Since the other configuration is the same as that of the first embodiment, the description thereof will be omitted.

According to the second embodiment described above, it is possible to provide an acoustic wave device having superior temperature characteristics and more suppressing spurious, and improving Q value.

### Third Embodiment

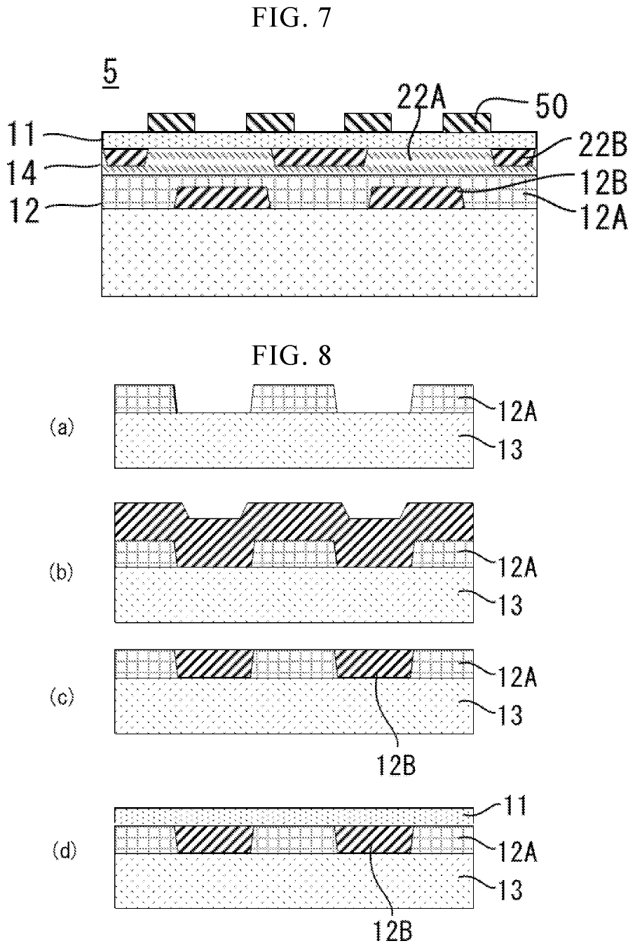

FIG. 7 is a cross-sectional showing the device chip 5 of the acoustic wave device 1 according to a third embodiment. As shown in FIG. 7, the second medium layer 14 of the device chip 5 of the acoustic wave device 1 according to the third embodiment includes third acoustic velocity regions 22A and fourth acoustic velocity regions 22B.

The third acoustic velocity regions 22A are formed of, for example, silicon nitride, silicon oxynitride, silicon, alumina, silicon dioxide, silicon carbide, germanium, tungsten, platinum, or iridium. The fourth acoustic velocity regions 22B are formed of, for example, silicon nitride, silicon oxynitride, silicon, alumina, silicon dioxide, silicon carbide, germanium, tungsten, platinum, or iridium, but are formed of a material other than the material employed in the third acoustic velocity regions 22A.

The fourth acoustic velocity regions 22B may be formed to be exposed to the piezoelectric substrate 11 side. Alternatively, the fourth acoustic velocity regions 22B may be formed so as not to be exposed to the piezoelectric substrate 11 side. The fourth acoustic velocity regions 22B may be formed so as to be exposed to the medium layers 12 side. Alternatively, the fourth acoustic velocity regions 22B may be formed so as not to be exposed to the medium layers 12 side.

According to another embodiment, the fourth acoustic velocity regions 22B may be formed through the third acoustic velocity regions 22A. That is, the second medium layer 14 may be formed so as to expose the fourth acoustical velocity regions 22B both on the piezoelectric substrate 11 side and on the medium layer 12 side.

As shown in FIG. 7, the fourth acoustic velocity regions 22B may be formed in regions that do not overlap with the second acoustic velocity regions 12B from the point of top view.

A third medium layer may be formed between the second medium layer 14 and the piezoelectric substrate 11. The third medium layer may be appropriately formed of a material such as silicon nitride, silicon oxynitride, silicon, alumina, silicon dioxide, and silicon carbide. The thickness of the third medium layer may be, for example, 0.1 μm to 5 μm.

The third acoustic velocity regions 22A and the fourth acoustic velocity regions 22B are configured so that the average acoustic velocity of the bulk wave propagating through the second medium layer 14 is higher than the velocity of the acoustic wave of the main mode excited by the acoustic wave elements 50 as a resonator. The velocity of the acoustic wave in the main mode excited by the acoustic wave elements 50 as a resonator is an acoustic velocity determined by the resonance frequency and the structure of the resonator. The average acoustic velocity is represented by (L1+L2)/((L1/V1)+(L2/V2)) when an acoustic wave passes through a medium consisting of a first medium (length is L1 and acoustic velocity is V1) and a second medium (length is L2 and acoustic velocity is V2).

According to an example, the average acoustic velocity of the bulk wave propagating through the second medium 14 may be from 4500 m/s to 5500 m/s. This facilitates confinement of the acoustic wave in the piezoelectric substrate 11. The average acoustic velocity of the bulk wave propagating through the second medium layer 14 is preferably 1.1 times or more, more preferably 1.2 times or more, and even more preferably 1.3 times or more than the acoustic velocity of the bulk wave propagating through the piezoelectric substrate 11. If the average acoustic velocity of the bulk waves propagating through the second medium layer 14 is too high, the bulk waves tend to be reflected at the boundary between the second medium layer 14 and the piezoelectric substrate 11, which may increase spurious.

Therefore, the average acoustic velocity of the bulk wave propagating through the second medium layer 14 is preferably 2.5 times or less, more preferably 2.0 times or less than the acoustic velocity of the bulk wave propagating through the piezoelectric substrate 11. Even if the acoustic velocity of the bulk wave propagating in the fourth acoustic velocity region 22B is 2.5 times or more than the acoustic velocity of the bulk wave propagating in the second medium layer 14, it is desirable to arrange the fourth acoustic velocity region 22B so that the bulk wave reflected in the fourth acoustic velocity region 22B does not resonate. The first acoustic velocity region 12A and the second acoustic velocity region 12B may be configured so that the acoustic velocity of the bulk wave propagating in the medium layer 12 is higher than the average acoustic velocity propagating in the second medium layer 14.

According to the third embodiment described above, it is possible to provide an acoustic wave device having superior temperature characteristics and more suppressing spurious, and improving Q value.

Next, a method of producing the acoustic wave device 1 according to the first embodiment will be described. FIG. 8 is a diagram for explaining the method for producing the acoustic wave device 1.

As shown in FIG. 8 part (a), a first acoustic velocity film is formed on the support substrate 13. Then, the first acoustic velocity film is patterned. In the patterning step, a method such as a lift-off method or an etching method is appropriately selected according to the material of the first acoustic velocity film.

As shown in FIG. 8 part (b), a second acoustic velocity material is filled in a region which the first acoustic velocity film is removed from by the patterning step. As the filling method of the second acoustic velocity material, a method such as a squeegee method, an evaporation method, or a sputtering method is appropriately selected according to the material.

As shown in FIG. 8 part (c), the second acoustic velocity material is polished until the first acoustic velocity film is exposed. In the polishing step, a chemical polishing method or a mechanical polishing method is appropriately selected according to the material.

As shown in FIG. 8 part (d), the piezoelectric substrate 11 is bonded after the polishing step. The acoustic wave elements 50 are configured to obtain desired device characteristics on the piezoelectric substrate 11 and the acoustic wave device 1 according to the first embodiment is obtained by the packaging process.

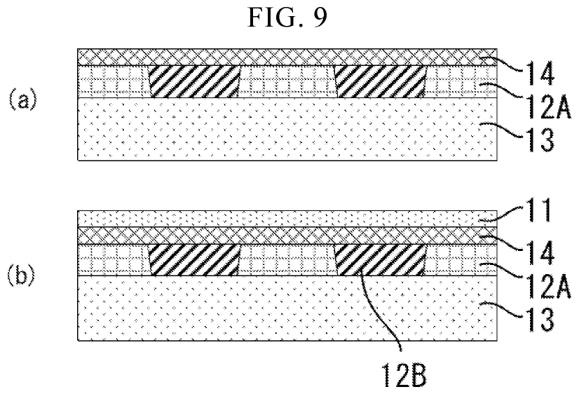

Next, a method of producing the acoustic wave device 1 according to the second embodiment will be described. FIG. 9 is a diagram for explaining the method for producing the acoustic wave device 1 according to the second embodiment.

As shown in FIG. 9 part (a), the material of the second medium layer 14 is applied after the polishing step of FIG. 8 part (c). The second medium layer 14 is appropriately formed of a material such as silicon nitride, silicon oxynitride, silicon, alumina, silicon dioxide, or silicon carbide.

The material of the second medium layer 14 is polished after the material of the second medium layer 14 is applied. In the polishing step, a chemical polishing method or a mechanical polishing method is appropriately selected according to the material. In the polishing step, the thickness of the second medium layer 14 can be polished to be, for example, 0.1 μm to 5 μm.

As shown in FIG. 9 part (b), the piezoelectric substrate 11 is bonded after the polishing step. The acoustic wave elements 50 are configured to obtain desired device characteristics on the piezoelectric substrate 11 and the acoustic wave device 1 according to the second embodiment is obtained by the packaging process.

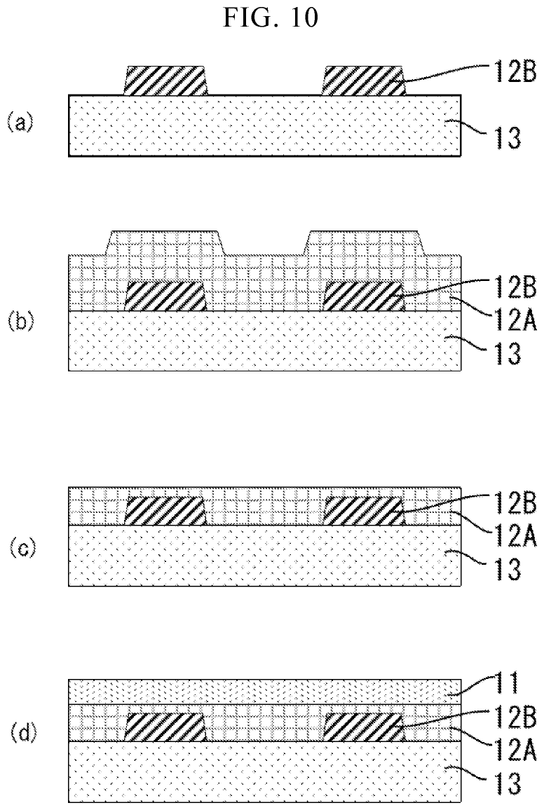

Next, a method of producing the acoustic wave device 1 according to the second embodiment will be described. FIG. 10 is a diagram for explaining the second method for producing the acoustic wave device 1.

As shown in FIG. 10 part (a), a second acoustic velocity film is formed on the support substrate 13. Then, the second acoustic velocity film is patterned. In the patterning step, a method such as the lift-off method or the etching method is appropriately selected according to the material of the second acoustic velocity film.

As shown in FIG. 10 part (b), a first acoustic velocity material is filled in a region which the second acoustic velocity film is removed from by the patterning step. As the filling method of the first acoustic velocity material, a method such as the squeegee method, the evaporation method, or the sputtering method is appropriately selected according to the material.

As shown in FIG. 10 part (c), the first acoustic velocity material is polished. It may be polished until the second acoustic velocity film is exposed or not. In the polishing step, the chemical polishing method or the mechanical polishing method is appropriately selected according to the material.

As shown in FIG. 10 part (d), the piezoelectric substrate 11 is bonded after the polishing step. The acoustic wave elements 50 are configured to obtain desired device characteristics and the acoustic wave device 1 is obtained by the packaging process.

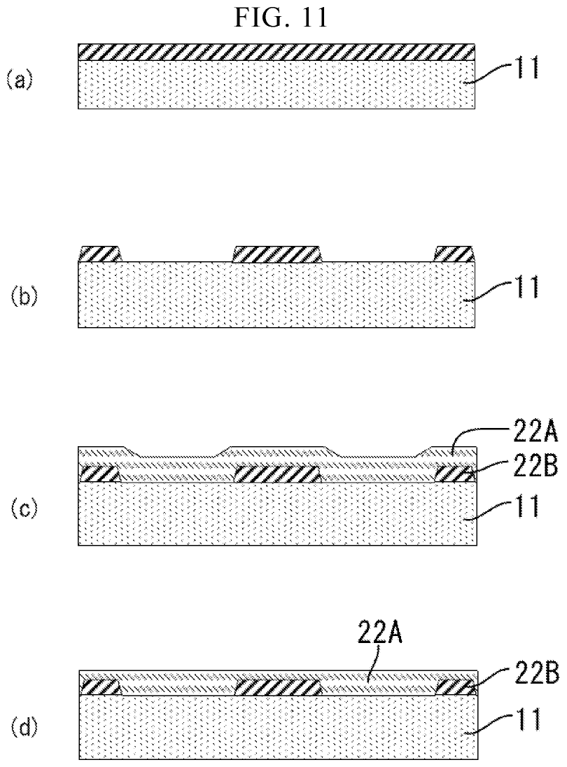

Next, a method of producing the acoustic wave device 1 according to a third embodiment will be described. FIG. 11 is the diagram for explaining the method for producing the acoustic wave device 1 according to the third embodiment.

As shown in FIG. 11 part (a), a fourth acoustic velocity film is formed on the piezoelectric substrate 11. Then, the fourth acoustic velocity film is patterned as shown in FIG. 11 part (b). In the patterning step, a method such as the lift-off method or the etching method is appropriately selected according to the material of the fourth acoustic velocity film.

As shown in FIG. 11 part (c), a third acoustic velocity material is filled in a region which the fourth acoustic velocity film is removed from by the patterning step. As the filling method of the third acoustic velocity material, a method such as the squeegee method, the evaporation method, or the sputtering method is appropriately selected according to the material.

As shown in FIG. 11 part (d), the third acoustic velocity material is polished. It may be polished until the fourth acoustic velocity film is exposed or not. In the polishing step, the chemical polishing method or the mechanical polishing method is appropriately selected according to the material.

After the polishing step, the support substrate 13 and the medium layer 12 which are obtained after the polishing step explained above with the FIG. 10 part (c) are bonded. The acoustic wave elements 50 are configured to obtain desired device characteristics and the acoustic wave device 1 according to the third embodiment is obtained by the packaging process.

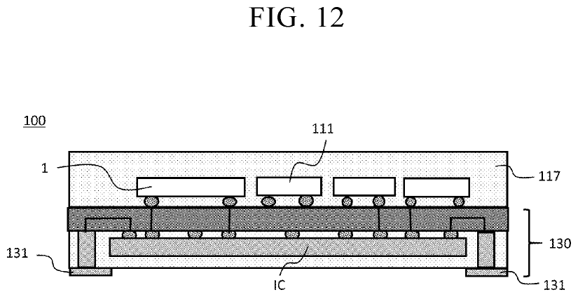

FIG. 12 is a longitudinal sectional view of a module to which the acoustic wave device 1 is applied according from the first embodiment to the third embodiment. The same or corresponding parts with the first embodiment to third embodiment are denoted by the same reference numerals. Duplicate descriptions of such portions may be simplified or omitted.

A module 100 includes a wiring substrate 130, a plurality of external connecting terminals 131, an integrated circuit component IC, the acoustic wave device 1, an inductor 111, and a sealing portion 117 in FIG. 12.

The plurality of external connection terminals 131 are formed on the lower surface of the wiring substrate 130. The plurality of external connection terminals 131 are mounted on the motherboard of the mobile communication terminal which is set in advance.

For example, the integrated circuit component IC is mounted inside the wiring substrate 130. The integrated circuit component IC includes a switching circuit and a low noise amplifier.

The acoustic wave device 1 is mounted on the main surface of the wiring substrate 130.

The inductor 111 is mounted on the main surface of the wiring substrate 130. The inductor 111 is mounted for impedance matching. For example, the inductor 111 is Integrated Passive Device (IPD).

The sealing portion 117 seals a plurality of electronic components including the acoustic wave device 1.

The module 100 described above includes the acoustic wave device 1. Therefore, it is possible to provide an acoustic wave device having superior temperature characteristics and more suppressing spurious.

While several aspects of at least one embodiment have been described, it is to be understood that various modifications and improvements will readily occur to those skilled in the art. Such modifications and improvements are intended to be part of the present disclosure and are intended to be within the scope of the present disclosure.

It is to be understood that the embodiments of the methods and apparatus described herein are not limited in application to the structural and ordering details of the components set forth in the foregoing description or illustrated in the accompanying drawings. Methods and apparatus may be implemented in other embodiments or implemented in various manners.

Specific implementations are given here for illustrative purposes only and are not intended to be limiting.

The phraseology and terminology used in the present disclosure are for the purpose of description and should not be regarded as limiting. The use of “including,” “comprising,” “having,” and variations thereof herein means the inclusion of the items listed hereinafter and equivalents thereof, as well as additional items.

The reference to “or” may be construed so that any term described using “or” may be indicative of one, more than one, and all of the terms of that description.

References to front, back, left, right, top, bottom, and side are intended for convenience of description. Such references are not intended to limit the components of the present disclosure to any one positional or spatial orientation. Accordingly, the foregoing description and drawings are by way of example only.

What is claimed is:

1. An acoustic wave device comprising:
a support substrate;
a medium layer formed on the support substrate;
a piezoelectric substrate formed on the medium layer; and
a resonator formed on the piezoelectric substrate,
wherein the medium layer includes a first acoustic velocity region and a second acoustic velocity region having different acoustic velocity from that of the first acoustic velocity region, the second acoustic velocity region penetrating at least one half of the thickness of the medium layer.

2. The acoustic wave device according to claim 1, in a top view,
wherein the second acoustic velocity regions includes a plurality of divided regions, and
wherein three or more of the second acoustic velocity regions are formed in a region where the resonator is formed.

3. The acoustic wave device according to claim 1, wherein an average acoustic velocity of a bulk wave propagating through the medium layer is higher than a velocity of an acoustic wave of a main mode excited by the resonator in a region overlapping with a region where the resonator is formed in a top view.

4. The acoustic wave device according to claim 1, wherein an average acoustic velocity of a bulk wave propagating through the medium layer is from 4500 m/s to 5500 m/s.

5. The acoustic wave device according to claim 1, further comprising a second medium layer formed between the medium layer and the piezoelectric substrate.

6. The acoustic wave device according to claim 5, wherein the second medium layer comprising a third acoustic velocity region and a fourth acoustic velocity region having different acoustic velocity from that of the third acoustic velocity region in a top view.

7. The acoustic wave device according to claim 5, further comprising a third medium layer formed between the second medium layer and the piezoelectric substrate.

8. The acoustic wave device according to claim 1, wherein the second acoustic velocity region includes a circular shape, an elliptical shape, or a polygonal shape in a top view.

9. The acoustic wave device according to claim 1, wherein the support substrate is made of sapphire, silicon, alumina, spinel, quartz, or glass.

10. The acoustic wave device according to claim 1, wherein the first acoustic velocity region comprises silicon nitride, silicon oxynitride, silicon, alumina, silicon dioxide, or silicon carbide.

11. The acoustic wave device according to claim 1, wherein the second acoustic velocity region comprises silicon nitride, silicon oxynitride, silicon, alumina, silicon dioxide, silicon carbide, germanium, tungsten, platinum, or iridium.

12. The acoustic wave device according to claim 1, wherein an average area of the second acoustic velocity region is 0.1 μm² to 500 μm².

13. A module comprising the acoustic wave device according to claim 1.

14. A method for producing an acoustic wave device, the method comprising:
a step of forming a first acoustic velocity film on a support substrate;
a step of patterning the first acoustic velocity film;
a step of filling a second acoustic velocity material in a region where the first acoustic velocity film is removed in the patterning step; and
a step of polishing the second acoustic velocity material until the first acoustic velocity film is exposed.

15. A method for producing an acoustic wave device, the method comprising:
a step of forming a second acoustic velocity film on a support substrate;
a step of patterning the second acoustic velocity film;
a step of filling a first acoustic velocity material in a region where the second acoustic velocity film is removed in the patterning step and covering with the second acoustic velocity film; and
a step of polishing the second acoustic velocity material so that the first acoustic velocity film is not exposed.
